(19) United States
(12) Patent Application Publication
(10) Pub. No.: US 2017/0170048 A1
(43) Pub. Date: Jun. 15, 2017

(54) WAFER HANDLER FOR INFRARED LASER RELEASE

(71) Applicant: GLOBALFOUNDRIES INC., Grand Cayman (KY)

(72) Inventors: Thuy Tran-Quinn, Katonah, NY (US); Daewon Yang, Niskayuna, NY (US); Matthew S. Angyal, Stormville, NY (US); Dennis M. Sheehan, Poughkeepsie, NY (US)

(73) Assignee: GLOBALFOUNDRIES INC., GRAND CAYMAN (KY)

(21) Appl. No.: 14/964,228

(22) Filed: Dec. 9, 2015

(51) Int. Cl. H01L 21/683; B32B 43/00

(52) U.S. Cl. CPC H01L 21/6835; B32B 43/006; H01L 2221/68318; H01L 2221/68381; B32B 2307/412; B32B 2307/204

(57) ABSTRACT

A wafer handler includes a substrate having a front surface and a back surface, an antireflective layer formed over the back surface, a silicon nitride compensation layer formed over the front surface, and a release layer formed over the compensation layer. The wafer handler can be bonded to a device wafer for processing of the device wafer, and debonded from the device wafer using infrared radiation without damaging the device wafer or devices formed thereon.

### BACKGROUND

The present application relates generally to wafer handlers, and more specifically to a wafer handler having a compressive compensation layer and methods of use.

During the manufacture of semiconductor devices, complex architectures are formed in and on a device substrate using a multitude of process steps including, inter alia, thin film deposition, photolithography, etching, ion implantation, and grinding, including the backside formation of redistribution (RDL) and flip-chip (C4) structures. These process steps together with their associated thermal budget contribute to the accumulation of stresses in the device substrate and its attendant deformation as a result of such stresses. An example substrate is a silicon wafer.

A handler wafer such as a glass or silicon wafer is commonly used to support the device substrate during processing, i.e., after wafer thinning The handler wafer is releasably bonded to the device wafer and provides mechanical support and structural rigidity thereto, which are important to support a thinned device wafer during various stages of the process flow to build RDL inductors and bumps. A thinned device wafer thickness may be less than 60 microns, for example. However, bonding as well as de-bonding of the device wafer to the handler wafer can be challenging in view of both pre-existing stresses in the device wafer and the accumulation of additional process-induced stresses in the device wafer while it is bonded to the handler wafer. Such stresses manifest as wafer bow or warp.

In view of the foregoing, it would be advantageous to provide a robust handler wafer adapted to economically bond to and debond from a device wafer while avoiding damage to the device wafer and the device structures formed thereon. Such a handler will efficiently shepherd the device wafer through the requisite process flow.

### SUMMARY

In accordance with embodiments of the present application, a wafer handler includes a substrate having a front surface and a back surface, an antireflective layer formed over the back surface, a silicon nitride compensation layer formed over the front surface, and a release layer formed over the compensation layer. The wafer handler can be bonded to a device wafer for processing of the device wafer, and debonded from the device wafer using infrared radiation without damaging the device wafer or devices formed thereon.

A related wafer assembly includes a device wafer bonded to such a wafer handler. In embodiments, the device wafer includes a substrate and a device layer disposed over the substrate, where the device wafer is bonded to the wafer handler via an adhesive layer disposed at the interface between the device layer and the release layer.

A method of de-bonding a device wafer from a wafer handler includes irradiating a wafer assembly with mid-wavelength infrared radiation, the wafer assembly including a device wafer bonded to a wafer handler, wherein the device wafer is bonded to the wafer handler via an adhesive layer disposed at the interface between the device layer and the release layer.

### BRIEF DESCRIPTION OF SEVERAL VIEWS OF THE DRAWINGS

The following detailed description of specific embodiments of the present application can be best understood when read in conjunction with the following drawings, where like structure is indicated with like reference numerals and in which:

FIG. 1 is a schematic diagram of a wafer handler according to embodiments;

FIG. 2 is a schematic diagram of a wafer handler and a device wafer;

FIG. 3 shows a method of de-bonding a device wafer from a wafer handler; and

FIG. 4 shows a device wafer after IR-induced separation from a wafer handler.

### DETAILED DESCRIPTION

Reference will now be made in greater detail to various embodiments of the subject matter of the present application, some embodiments of which are illustrated in the accompanying drawings. The same reference numerals will be used throughout the drawings to refer to the same or similar parts.

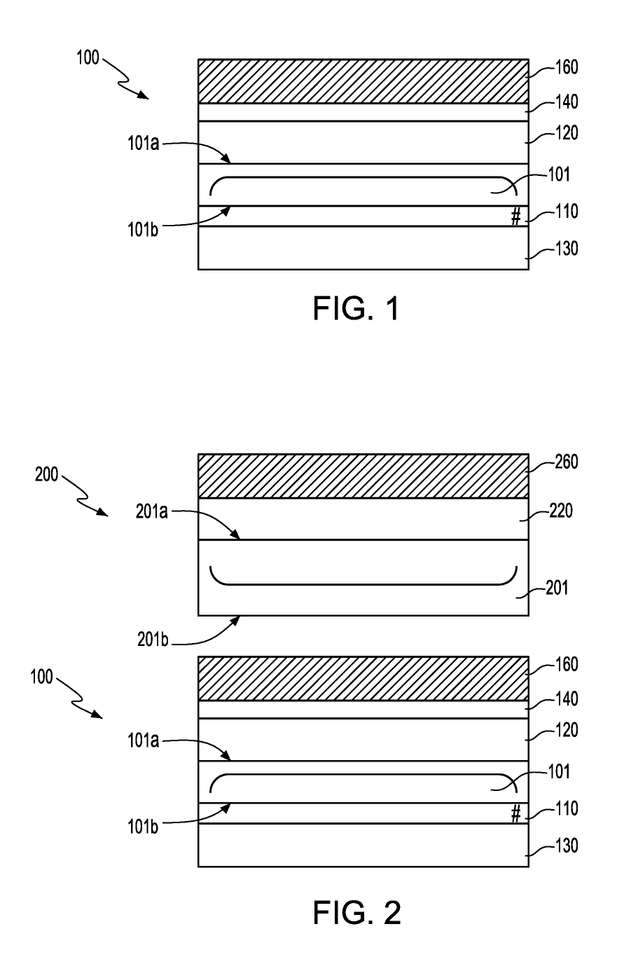

Disclosed are wafer handler structures, as well as their methods of manufacture and their methods of use. A wafer handler 100 is depicted in FIG. 1. The wafer handler 100 comprises a wafer handler substrate 101. Substrate 101 has a front surface 101a and a back surface 101b. Typically, an identifying serial number (#) is etched in the back surface 101b. The wafer handler substrate 101 may be doped or undoped silicon, germanium, gallium arsenide, sapphire, or alloys thereof. The dopant may be a p-type dopant or an n-type dopant. The term “p-type” refers to the addition of impurities to an intrinsic semiconductor that create deficiencies of valence electrons. In a silicon-containing semiconductor material, examples of p-type dopants, i.e., impurities, include, but are not limited to, boron, aluminum, gallium and indium. “N-type” refers to the addition of impurities that contributes free electrons to an intrinsic semiconductor. In a silicon-containing semiconductor material, examples of n-type dopants, i.e., impurities, include, but are not limited to, antimony, arsenic and phosphorous.

Disposed over the back surface 101b of substrate 101 is an adhesion layer 110 and an enhanced release layer 130. In the illustrated embodiment, the adhesion layer 110 is formed in contact with substrate 101 and the enhanced release layer 130 is formed in contact with the adhesion layer 110.

In various embodiments, the adhesion layer 110 includes a dielectric material such as silicon oxide and the enhanced release layer 130 comprises silicon nitride (e.g., Si₃N₄). Further example adhesion layer materials include oxides and oxynitrides of aluminum, hafnium, zirconium, lanthanum, titanium, strontium, yttrium, as well as alloys and combinations thereof. The thickness of the adhesion layer 110 may be 5 nm to 20 nm. The thickness of the enhanced release layer may be 150 nm to 300 nm. The adhesion layer 110 and the enhanced release layer 130 may each be formed using a chemical vapor deposition (CVD) process such as plasma enhanced chemical vapor deposition (PECVD).

A PECVD silicon oxide adhesion layer can be deposited using a combination of silicon precursor gases such as dichlorosilane or silane, and oxygen precursors such as oxygen and nitrous oxide, typically at pressures from a few millitorr to a few torr. An additional silicon oxide precursor is tetraethylorthosilicate (TEOS). Typically silane deposits between 300° C. and 500° C., dichlorosilane at around 900° C., and TEOS between 650° C. and 750° C.

A PECVD silicon nitride enhanced release layer can be deposited using a combination of silicon precursor gases such as silane (SiH₄), dichlorosilane (SiCl₂H₂) or silicon tetrachloride (SiCl₄), and a source of nitrogen such as nitrogen gas (N₂) or ammonia (NH₃).

The enhanced release layer 130 may be an antireflective layer. An example enhanced release layer 130 of this type has a transmittance of at least 80% over the mid-wavelength infrared spectrum (e.g., 80, 85, 90 or 95%, including ranges between any of the foregoing). The mid-wavelength infrared spectrum is characterized by wavelengths in the range of 3 to 8 microns. Any antireflective coating (ARC) material that can reduce image distortions associated with reflections off the surface of an underlying structure may be employed in the present application as the antireflective layer. In one example, the antireflective layer may include a silicon (Si)-containing antireflective coating material. The antireflective coating material can be formed by spin-on coating, chemical vapor deposition including plasma enhanced chemical vapor deposition, evaporation or chemical solution deposition. The thickness of the ARC can be from 10 nm to 150 nm, although lesser and greater thicknesses can also be employed.

In further embodiments, the enhanced release layer 130 may bean optically transparent layer. An example enhanced release layer 130 of this type has a transmittance of at least 80% over the visible spectrum (e.g., 80, 85, 90 or 95%, including ranges between any of the foregoing). The enhanced release layer 130 may be sufficiently optically transparent to enable viewing of the wafer handler substrate serial number (#) through the layer. The IR and optical transmittance of the enhanced release layer 130 may be controlled, for example, by varying the ratio of silicon precursor gas to nitrogen source gas (e.g., SiH₄/NH₃) during the deposition process.

With reference still to FIG. 1, disposed over the front surface 101a of substrate 101 is a stress compensation layer 120, a release layer 140, and an adhesive layer 160. In the illustrated embodiment, the stress compensation layer 120 is formed in contact with substrate 101, the release layer 140 is formed in contact with the compensation layer 120, and the adhesive layer 160 is formed in contact with the release layer 140. In embodiments, the compensation layer 120 is a compressive layer. In alternate embodiments, the compensation layer 120 is a tensile layer. As illustrated schematically, the formation of a compressive compensation layer 120 over the substrate front surface 101a produces a convex (downward bending) bow in substrate 101. As used herein, the front surface 101a of the substrate is the device wafer-facing surface of the wafer handler.

In various embodiments, the stress compensation layer 120 comprises silicon nitride having a thickness of 300 nm to 500 nm (e.g., 300, 350, 400, 450 or 500 nm, including ranges between any of the foregoing values) wherein the compensation layer 120 is a highly compressive layer that induces a bow in substrate 101 of 500 to 800 microns, e.g., 500, 600, 700 or 800 microns, including ranges between any of the foregoing values. The compensation layer 120 may be formed using high density (>10¹¹ ions/cm³) plasma. An example high density plasma process for forming the compensation layer 120 uses an inductively coupled plasma (ICP) discharge or a capacitively coupled plasma (CCP) discharge, a plasma power of 200 W to 2 kW, and a substrate temperature of less than or equal to 500° C. (e.g., 350, 400, 450 or 500° C.). Suitable gas chemistries include SiH₄/N₂/Ar and SiH₄/NH₃/He, as well as combinations and permutations thereof.

An example process tool for implementing a high density plasma (HDP) process is a 300 mm Lam Speed HDP chemical vapor deposition tool (Lam Research, Ltd.). Argon and nitrogen can be used as sputtering source gases, at flow rates of 200 sccm to 300 sccm (e.g., 230 sccm) and 300 sccm to 400 sccm (e.g., 310 sccm) respectively, for 300 mm substrates. During the sputtering process the chamber pressure is less than 10 mTorr. The low frequency (LF) power can range from 1500 W to 4000 W (e.g., 1500-2000 W for 200 mm wafers and 3000-4000W for 300 mm wafers), and the high frequency (HF) bias power can range from 200 W to 3000 W (e.g., 200-2000 W for 200 mm wafers and 400-3000 W for 300 mm wafers). The high frequency bias power is typically supplied by an RF generator at 13.56 MHz.

While a stress compensation layer 120 is disposed over the front surface 101a of substrate 101, in embodiments the back surface 101b of substrate 101 is free of a compensation layer, i.e., the layer(s) disposed on the back surface 101b of substrate 101 do not have an appreciable effect on substrate bow or warp. The combined adhesion layer 110 and enhanced release layer 130, for example, induce a bow in substrate 101 of less than 100 microns.

As used herein, ‘bow’ and ‘warp’ are complimentary measures of the flatness of a wafer or semiconductor substrate. For a wafer having a median surface defined as the locus of points in the wafer equidistant between the front and back surfaces, wafer bow is equal to the deviation of the center point of the median surface of a free, unclamped wafer from the median surface reference plane established by three points equally spaced on a circle with a diameter a specified amount less than the nominal diameter of the wafer (ASTM F534).

When measuring and calculating bow, the location median surface of the wafer must be known. By measuring deviations of the median surface, localized thickness variations at the center point of the wafer are removed from the calculation.

Because bow is measured at the center point of the wafer only, a three (3) point reference plane about the edge of the wafer is calculated. The value of bow is then calculated by measuring the location of the median surface at the center of the wafer and determining its distance from the reference plane. Bow can be positive or negative. A positive value indicates that the center point of the median surface is above the three point reference plane, while a negative value indicates that the center point of the median surface is below the three point reference plane. In embodiments, high bow is the result of device-side metallization and the attendant stress that is induced by the formation of metal layers on the wafer. As used herein, a ‘high bow’ wafer (e.g., a 200 mm or greater diameter wafer) exhibits a bow in excess of 150 microns.

Like bow, warp is a measurement of the differentiation between the median surface of a wafer and a reference plane. Warp, however, uses the entire median surface of the wafer instead of only the position at the center point. By looking at the entire wafer, warp provides a measurement of true wafer shape. Warp is defined as the differences between the maximum and minimum distances of the median surface of a free, unclamped wafer from a reference place (ASTM F1390).

The location of the median surface is calculated as it is for bow. For warp determination, there are typically two choices for construction of the reference plane. One is the same three point plane around the edge of the wafer. The other is by performing a least squares fit calculation of median surface data acquired during the measurement scan. Warp is then calculated by finding the maximum deviation from the reference plane (RPDmax) and the minimum differentiation from the reference plane (RPDmin). RPDmax is defined as the largest distance above the reference plane and is a positive number. RPDmin is the largest distance below the reference plane and is a negative number. Warp is equal to RPDmax−RPDmin

Formed over the compensation layer 120 is a low melting point (Tₘ<700° C.) or low oxidizing temperature release layer 140. The release layer 140 may be a thin (5-20 nm) metal or metal alloy layer such as, for example, aluminum. The release layer 140 may include a porous polymer. The release layer 140 may be formed by a physical vapor deposition (PVD) process such as sputtering. According to various embodiments, the release layer has a melting point between 300° C. and 700° C., e.g., 300, 400, 500, 600 or 700° C., including ranges between any of the foregoing values.

### Examples

Referring now to FIG. 2, shown is a wafer handler 100 as disclosed herein and a semiconductor device wafer 200. The semiconductor device wafer 200 includes a substrate 201 such as a silicon substrate, which may include through substrate vias (TSVs) that extend at least partially through the substrate 201. Substrate 201 has a front surface 201a and a back surface 201b. A plurality of semiconductor devices, which are shown collectively as device layer 220, are formed on the substrate front surface 201a. Each of the semiconductor devices may comprise transistors, capacitors, other components and various wirings, all of which are not shown for clarity. An adhesive layer 260 is disposed over the device layer 220.

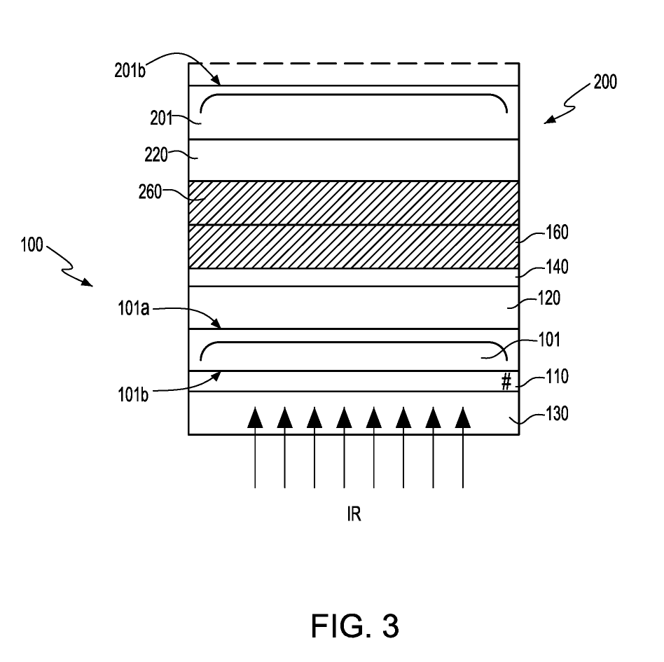

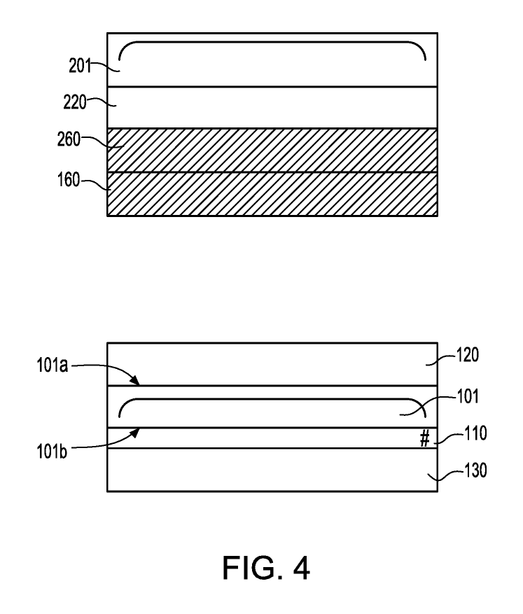

Referring to FIG. 3, the semiconductor device wafer 200 is flipped over so that the adhesive layer 260 on the semiconductor device wafer 200 faces the adhesive layer 160 on the wafer handler 100. With the bow of the semiconductor wafer 200 substantially replicated by the wafer handler 100, the wafer handler 100 and the semiconductor device wafer 200 undergo a thermal compression bonding process in which the adhesive layers 160, 260 adhere to one another.

Example materials for adhesive layers 160, 260 include organic polymers such as SU-8 or benzocyclobutene (BCB), though other adhesive materials can be used. Bonding with such materials is based on polymerization of organic molecules to form long chains during curing. These cross-linking reactions transform the organic polymer to a solid polymer layer.

In an example method, an intermediate adhesive layer is applied by, for example, spinning, spraying, printing, embossing, or dispensing onto a surface. The adhesive layer thickness depends on viscosity and the parameters used for its application (e.g., spin speed and pressure). The hardening conditions also depend on the choice of adhesive. By way of example, hardening of the adhesive may be possible using one or more of temperature, pressure and irradiation (e.g., UV light).

SU-8, for example, is a 3 component UV-sensitive negative photo-resist based on epoxy resin, gamma butyrolactone and triarylsulfonium salt. SU-8 polymerizes at approximately 100° C. and is temperature-stable up to 150° C. Benzocyclobutene (BCB) has a low dielectric constant and dielectric loss. The polymerization of BCB occurs at a temperature of 250 to 300° C.; BCB is thermally stable up to 350° C. These polymer adhesives are CMOS and bio-compatible and have excellent electrical, mechanical and fluidic properties. The aforementioned polymer adhesives also have a high cross-linking density and high chemical resistance.

In an example process, an adhesive layer is spin or spray coated, usually 1 to 50 μm thick, to the surfaces to be bonded. The substrates with the intermediate layer are pressed together with subsequent thermal curing that results in a substrate-to-substrate bond. The precise temperature and the curing time are variable; a lower curing time can be achieved with a higher curing temperature. After curing, a post-bake process can be used to hard-cure the adhesive layer. An example post-bake is performed at 180 to 320° C. for 30 to 240 min The adhesive is baked (e.g., 120° C. for 30 min) before curing to remove solvent. Curing can improve elasticity of the adhesive layer.

In embodiments, when bonded to the wafer handler the device wafer is held substantially rigid by the wafer handler such that no appreciable strain (deformation such as warp or bow) is sustained by the device wafer as a result of process-induced stresses.

Thereafter, the back surface 201b of the substrate may undergo a thinning process to reduce the thickness of the device wafer (indicated by dashed lines) and reveal the TSVs (if present). Redistribution level with or without inductors (RDL) and flip-chip (C4) structures may be formed on the back surface of the substrate 201 and the semiconductor device wafer 200 may then undergo a dicing process in which a saw or laser isolates the semiconductor devices formed thereon. Throughout processing of the bonded wafers, including the thinning of semiconductor device wafer 200, the serial number (#) on the wafer handler 100 can be read, e.g., by a laser reader, allowing tracking of the device wafer 200. Moreover, functional testing or other quality assurance evaluations may be performed on thinned device wafers while bonded to the wafer handler, whereas such testing is not readily performed on device wafers bonded to conventional glass handlers.

As shown in FIG. 3, with the handler waver 100 still adhered to the device wafer 200, the wafer handler 100 is exposed to mid-wavelength infrared radiation from a source such as a laser. The infrared radiation, which is incident upon the enhanced release layer 130, passes through the wafer handler 100 and is absorbed by the release layer 140. Through the absorption of infrared radiation, the release layer is ablated or otherwise degraded.

According to embodiments, it has been unexpectedly determined that an enhanced release layer 130 having a thickness of 300 nm or less (e.g., 150, 200, 250 or 300 nm, including ranges between any of the foregoing values) provides a working equilibrium between stress and strain and attenuates the energy of the incident infrared radiation, which minimizes radiation damage to the device wafer while allowing for the degradation of the release layer. When the release layer 140 is sufficiently heated, the device wafer 200 may be separated from the wafer handler 100 without delamination of the compensation layer or damage to the device wafer 200 or the devices formed thereon. Prior to the instant discovery, 3D high-bow device wafers could not be successfully bonded to a silicon handler and processed without delamination of a compensation layer.

Any suitable infrared radiation (IR) source can be used. One example IR source is an optically immersed 3.6 micron light emitting diode (LED) having a silicon lens and a quartz window (peak wavelength=3.6 microns; pulsed power at 1 A=350 μW; continuous wave (CW) power at 200 mA=130 μW; switching time ≦20 ns). A further example IR source is an optically immersed 4.7 micron light emitting diode (LED) having a silicon lens and a sapphire window (peak wavelength=4.7 microns; pulsed power at 1 A=25 μW; continuous wave (CW) power at 200 mA=5 μW; switching time ≦20 ns). In various embodiments, a power density of the IR treatment is in the range of 0.5 to 20 W/cm². The IR source can operate in pulsed or steady state mode.

The method described above may be used to process advanced node device wafers and fabricate integrated circuit chips that are thinned and, as such, handled by a wafer handler. The resulting thinned integrated circuit chips can be distributed as a single wafer that has multiple unpackaged chips, as a bare die, or packaged after they are removed from the wafer handler. In a packaged form, the chip may be mounted in a single chip package or in a multichip package. In various embodiments, the chip is then integrated with other chips, discrete circuit elements, and/or other signal processing devices as part of either an intermediate product, such as a motherboard, or an end product. The end product does not include the wafer handler disclosed herein.

As used herein, the singular forms “a,” “an” and “the” include plural referents unless the context clearly dictates otherwise. Thus, for example, reference to a “compensation layer” includes examples having two or more such “compensation layers” unless the context clearly indicates otherwise.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is no way intended that any particular order be inferred. Any recited single or multiple feature or aspect in any one claim can be combined or permuted with any other recited feature or aspect in any other claim or claims.

As used herein, a layer or region “disposed over” a substrate or other layer refers to formation above, or in contact with, a surface of the substrate or layer. For example, where it is noted or recited that a layer is disposed over a substrate or other layer, it is contemplated that intervening structural layers may optionally be present between the layer and the substrate.

While various features, elements or steps of particular embodiments may be disclosed using the transitional phrase “comprising,” it is to be understood that alternative embodiments, including those that may be described using the transitional phrases “consisting” or “consisting essentially of,” are implied. Thus, for example, implied alternative embodiments to an enhanced release layer that comprises silicon nitride include embodiments where an enhanced release layer consists essentially of silicon nitride and embodiments where an enhanced release layer consists of silicon nitride.

It will be apparent to those skilled in the art that various modifications and variations can be made without departing from the spirit and scope of the application. Since modifications, combinations, sub-combinations and variations of the disclosed embodiments incorporating the spirit and substance of the invention may occur to persons skilled in the art, the invention should be construed to include everything within the scope of the appended claims and their equivalents.

What is claimed as new is:

1. A wafer handler comprising:
a substrate having a front surface and a back surface;
an antireflective layer formed over the back surface;
a silicon nitride compensation layer formed over the front surface; and
a release layer formed over the compensation layer.

2. The wafer handler of claim 1, wherein the antireflective layer comprises PECVD silicon nitride.

3. The wafer handler of claim 1, wherein the antireflective layer thickness ranges from 150 nm to 300 nm.

4. The wafer handler of claim 1, wherein the antireflective layer has a mid-wavelength IR transmittance of at least 80%.

5. The wafer handler of claim 1, wherein the antireflective layer has an optical wavelength transmittance of at least 80%.

6. The wafer handler of claim 1, wherein the compensation layer is a compressive layer.

7. The wafer handler of claim 1, wherein the compensation layer comprises plasma CVD silicon nitride.

8. The wafer handler of claim 1, wherein the compensation layer thickness ranges from 300 nm to 500 nm.

9. The wafer handler of claim 1, wherein the compensation layer induces a bow in the substrate of 500 microns to 800 microns.

10. The wafer handler of claim 1, wherein the release layer has a melting point of less than 700° C.

11. The wafer handler of claim 1, wherein the release layer comprises a metal, a metal alloy or a porous polymer.

12. The wafer handler of claim 1, wherein the release layer comprises aluminum.

13. The wafer handler of claim 1, further comprising an adhesion layer between the back surface and the antireflective layer.

14. The wafer handler of claim 13, wherein the adhesion layer is a dielectric layer having a thickness of 5 nm to 20 nm.

15. The wafer handler of claim 1, further comprising an adhesive layer formed over the release layer.

16. A method of de-bonding a device wafer from a wafer handler, comprising:
irradiating a wafer assembly with mid-wavelength infrared radiation, the wafer assembly comprising a device wafer bonded to a wafer handler, wherein
the device wafer comprises a substrate and a device layer disposed over the substrate,
the wafer handler comprises a substrate having a front surface and a back surface, an antireflective layer formed over the back surface, a silicon nitride compensation layer formed over the front surface, and a release layer formed over the compensation layer, and
the device wafer is bonded to the wafer handler via an adhesive layer disposed at the interface between the device layer and the release layer.

17. The method of claim 16, wherein the infrared radiation is incident on the antireflective layer.

18. The method of claim 16, wherein the infrared radiation degrades the release layer to debond the device wafer from the wafer handler.

19. The method of claim 16, wherein the compensation layer comprises a compressive layer, the antireflective layer comprises silicon nitride, and the release layer comprises a metal, a metal alloy or a porous polymer.

20. A wafer assembly comprising a device wafer bonded to a wafer handler,
the device wafer comprising a substrate and a device layer disposed over the substrate,
the wafer handler comprising a substrate having a front surface and a back surface, an antireflective layer formed over the back surface, a silicon nitride compensation layer formed over the front surface, and a release layer formed over the compensation layer, wherein
the device wafer is bonded to the wafer handler via an adhesive layer disposed at the interface between the device layer and the release layer.
